(19) United States
(12) Patent Application Publication
(10) Pub. No.: US 2011/0017921 A1
(43) Pub. Date: Jan. 27, 2011

(54) Carbon nanotube film composite structure, transmission electron microscope grid using the same, and method for making the same

(75) Inventors: Kai-Li Jiang, Beijing (CN); Li-Na Zhang, Beijing (CN); Hao-Xu Zhang, Beijing (CN); Shou-Shan Fan, Beijing (CN)

Correspondence Address: Altis Law Group, Inc.;ATTN: Steven Reiss, 288 SOUTH MAYO AVENUE, CITY OF INDUSTRY, CA, 91789, US

(73) Assignees: Tsinghua University, Beijing City (CN); HON HAI Precision Industry CO., LTD., Tu-Cheng City (TW)

(21) Appl. No.: 12/590,632

(22) Filed: Nov. 12, 2009

(30) Foreign Application Priority Data
Jul. 24, 2009 (CN) 200910109128.0

(51) Int. Cl. H01J 37/20; B32B 5/18

(52) U.S. Cl. 250/440.11; 428/312.2; 977/742

(57) ABSTRACT

The present invention relates to a transmission electron microscope grid including graphene sheet-carbon nanotube film composite. The graphene sheet-carbon nanotube film composite structure includes at least one carbon nanotube film structure and at least one graphene sheet. The carbon nanotube film structure includes at least one pore. The pore is covered by the graphene sheet.

### CROSS-REFERENCE TO RELATED APPLICATIONS

This application claims all benefits accruing under 35 U.S.C. §119 from China Patent Application No. 200910109128.0, filed on 2009/7/24 in the China Intellectual Property Office, the disclosure of which is incorporated herein by reference. This application is related to commonly-assigned application entitled, “METHOD FOR PREPARING TRANSMISSION ELECTRON MICROSCOPE SAMPLE”, filed **** (Atty. Docket No. US28026).

### BACKGROUND

1. Technical Field

The present disclosure relates to a carbon nanotube film composite structure, a transmission electron microscope grid using the same, and a method for making the same.

2. Description of Related Art

Transmission electron microscopy is one of the most important techniques available for the detailed examination and analysis of very small materials. Transmission electron microscopy provides high resolution imaging and material analysis of thin specimens. In transmission electron microscopy analysis, a transmission electron microscope (TEM) grid is used to support the specimens. The conventional TEM grid includes a metal grid such as a copper or nickel grid, a porous organic membrane covering on the metal grid, and an amorphous carbon film deposited on the porous organic membrane. However, in practical application, when the size of the specimen's particle corresponds to or is less than the thickness of the supporting film, the amorphous carbon film induces high noise in the transmission electron microscopy imaging.

What is needed, therefore, is a TEM grid having higher resolution transmission electron microscopy images when the size of the specimen is nano in scale, and method for making the same.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a flow chart of one embodiment of a method for making a TEM grid.

FIG. 2 shows a Scanning Electron Microscope (SEM) image of a carbon nanotube film.

FIG. 3 shows an SEM image of a carbon nanotube film structure including at least two stacked carbon nanotube films of FIG. 2, aligned along different directions.

FIG. 4 is a schematic view of the TEM grid formed by the method of FIG. 1.

FIG. 5 is a schematic view of an embodiment of graphene sheet-carbon nanotube film composite structure.

FIG. 6 is a schematic view of an embodiment of graphene sheet-carbon nanotube film composite structure.

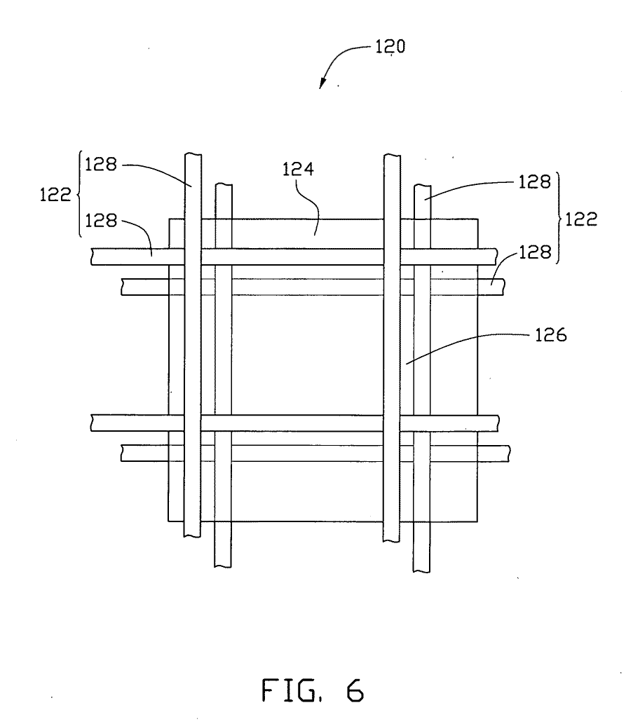

FIG. 7 shows a TEM image of an embodiment of the graphene sheet-carbon nanotube film composite structure.

FIG. 8 is a schematic view of an embodiment of the graphene sheet-carbon nanotube film composite structure with a specimen thereon.

FIG. 9 shows a TEM image of an embodiment with nano-scaled gold particles.

FIG. 10 shows a high resolution TEM image of an embodiment with the nano-scaled gold particles.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

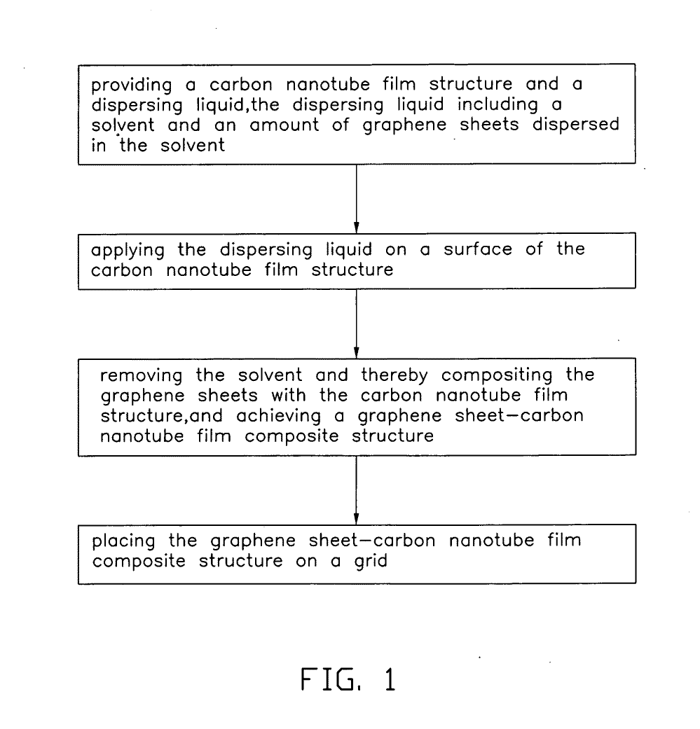

Referring to FIG. 1, a method for making a TEM grid in one embodiment includes:
(a) providing a carbon nanotube film structure and a dispersed solution, and the dispersed solution comprises a solvent and an amount of graphene sheets dispersed in the solvent;
(b) applying the dispersed solution on a surface of the carbon nanotube film structure;
(c) removing the solvent and thereby compositing the graphene sheets with the carbon nanotube film structure, and achieving a graphene sheet-carbon nanotube film composite structure; and
(d) placing the graphene sheet-carbon nanotube film composite structure on a grid.

In step (a), the carbon nanotube film structure includes at least two stacked carbon nanotube films aligned along different directions. The carbon nanotubes in the carbon nanotube film are aligned substantially along the same direction. In the carbon nanotube film structure, the length directions of the carbon nanotubes in different carbon nanotube films can intersect with each other. The carbon nanotube film can be drawn from a carbon nanotube array.

A method for making the carbon nanotube film includes: (a11) providing the carbon nanotube array capable of having a film drawn therefrom; and (a12) pulling/drawing out the carbon nanotube film from the carbon nanotube array. The pulling/drawing can be done by using a tool (e.g., adhesive tape, pliers, tweezers, or another tool allowing multiple carbon nanotubes to be gripped and pulled simultaneously).

In step (a11), a given carbon nanotube array can be formed by a chemical vapor deposition (CVD) method. The carbon nanotube array includes a plurality of carbon nanotubes parallel to each other and approximately perpendicular to the substrate. The carbon nanotubes in the carbon nanotube array are closely packed together by van der Waals attractive force. The carbon nanotubes in the carbon nanotube array can be single-walled carbon nanotubes, double-walled carbon nanotubes, multi-walled carbon nanotubes, or combinations thereof. The diameter of the carbon nanotubes can be in the range from about 0.5 nanometers to about 50 nanometers. The height of the carbon nanotubes can be in the range from about 50 nanometers to 5 millimeters. In one embodiment, the height of the carbon nanotubes can be in a range from about 100 microns to 900 microns.

In step (a12), the carbon nanotube film includes a plurality of carbon nanotubes, and there are interspaces between adjacent two carbon nanotubes. Carbon nanotubes in the carbon nanotube film can be substantially parallel to a surface of the carbon nanotube film. A distance between adjacent two carbon nanotubes can be larger than a diameter of the carbon nanotubes. The carbon nanotube film can be pulled/drawn by the following substeps: (a121) selecting a carbon nanotube segment having a predetermined width from the carbon nanotube array; and (a122) pulling the carbon nanotube segment at an even/uniform speed to achieve a uniform drawn carbon nanotube film.

In step (a121), the carbon nanotube segment having a predetermined width can be selected by using an adhesive tape such as the tool to contact the carbon nanotube array. The carbon nanotube segment includes a plurality of carbon nanotubes parallel to each other. In step (a122), the pulling direction is arbitrary (e.g., substantially perpendicular to the growing direction of the carbon nanotube array).

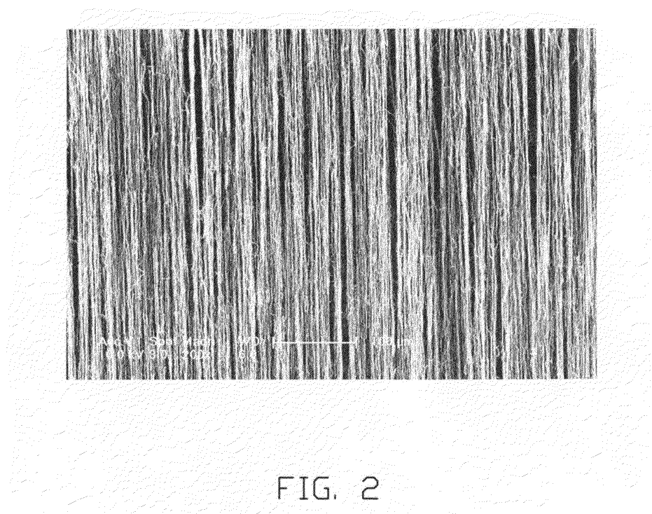

More specifically, during the pulling process, as the initial carbon nanotube segment is drawn out, other carbon nanotube segments are also drawn out end-to-end due to the van der Waals attractive force between ends of adjacent segments. This process of drawing ensures that a continuous, uniform carbon nanotube film having a predetermined width can be formed. Referring to FIG. 2, the carbon nanotube film includes a plurality of carbon nanotubes joined end-to-end. The carbon nanotubes in the carbon nanotube film are parallel to the pulling/drawing direction of the drawn carbon nanotube film, and the carbon nanotube film produced in such manner can be selectively formed to have a predetermined width. The carbon nanotubes in the carbon nanotube film are joined end-to-end by van der Waals attractive force therebetween to form a free-standing film. The term ‘free-standing’ includes films that do not have to be supported by a substrate. In the carbon nanotube film, the adjacent two carbon nanotubes side by side may be in contact with each other or spaced apart from each other. Pores are defined in the carbon nanotube film by adjacent carbon nanotubes.

In step (a), at least two carbon nanotube films are stacked with each other along different directions with an angle α therebetween. A frame can be provided, and a first carbon nanotube film can be secured to the frame. One or more edges of the carbon nanotube film are attached on the frame, and other part of the carbon nanotube film is suspended. A second carbon nanotube film can be placed on the first carbon nanotube film along another direction. By using the same manner, more than two carbon nanotube films can be stacked with each other on the frame. The carbon nanotube films can be respectively aligned along different directions, and can also be aligned along just two directions. The carbon nanotube film structure is a free-standing structure.

Adjacent carbon nanotube films can be combined only by the van der Waals attractive force therebetween and a more stable carbon nanotube film structure is formed. The layer number of the carbon nanotube films in the carbon nanotube film structure is not limited. In one embodiment, the carbon nanotube film structure consist of 2 to 4 layers of carbon nanotube films. The angle α between the orientations of carbon nanotubes in the two carbon nanotube films aligned along different directions can be larger than 0 degrees. In one embodiment, the angle α is about 90 degrees.

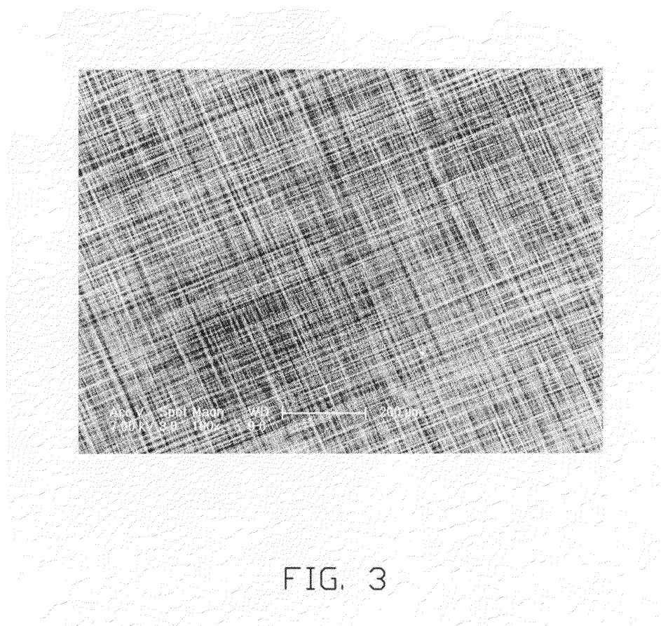

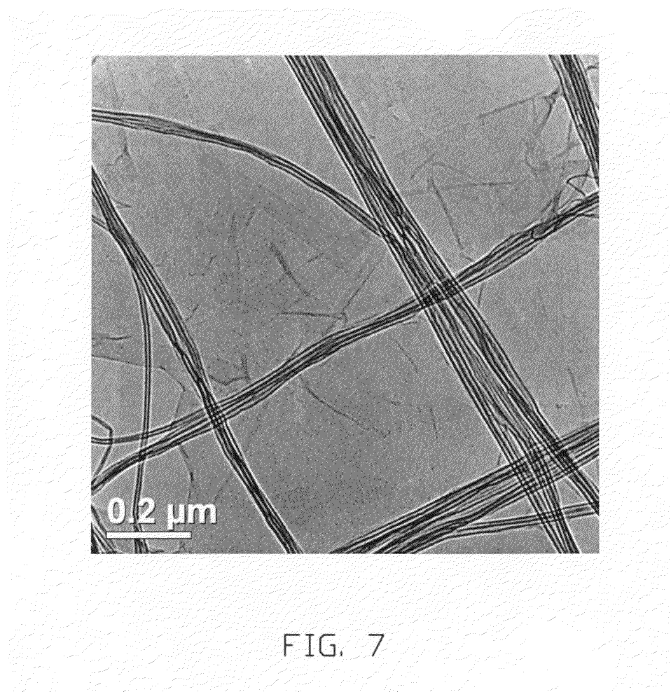

After forming the carbon nanotube film structure, the step (a) can further include an optional step (g) of treating the carbon nanotube film structure with an organic solvent. After an organic solvent is applied to the carbon nanotube film structure, the organic solvent can be evaporated from the carbon nanotube film structure, to enlarge the pores defined between adjacent carbon nanotubes in the carbon nanotube film structure. The organic solvent can be volatile at room temperature and can be selected from the group consisting of ethanol, methanol, acetone, dichloroethane, chloroform, and any combination thereof. In one embodiment, the organic solvent is ethanol. The organic solvent should have a desirable wettability relative to the carbon nanotubes. The step of applying the organic solvent on the carbon nanotube film structure can include a step of dropping the organic solvent on the surface of the carbon nanotube film structure by a dropper and/or a step of immersing the entire carbon nanotube film structure into a container with the organic solvent therein. Referring to FIG. 3 and FIG. 7, after the organic solvent is evaporated, the adjacent parallel carbon nanotubes in the carbon nanotube film will bundle together, due to the surface tension of the organic solvent when the organic solvent volatilizing. The bundling will create parallel and spaced carbon nanotube strings. Due to the edges of the carbon nanotube film structure can be held by the frame or other holder, the bundling can only occur in microscopic view, and the carbon nanotube film structure will sustain the film shape in macroscopic view. The carbon nanotube strings also include a plurality of carbon nanotubes joined end-to-end by Van der Waals attractive force therebetween. Due to the carbon nanotube films being aligned along different directions, the carbon nanotube strings shrunk from carbon nanotubes in different carbon nanotube films are intersect with each other, and thereby forming the plurality of pores. The size of the pore is ranged from about 1 nanometer to about 10 microns. In one embodiment, the size of the pore ranges from about 1 nanometer to about 900 nanometers. In one embodiment, the carbon nanotube film structure consists of 4 layers of carbon nanotube films, and above 60% of the pores are nano in scale. It is to be noted that, the more the layers of carbon nanotube films, the smaller the size of the pores in the carbon nanotube film structure. Thus, by adjusting the number of the carbon nanotube films in the carbon nanotube structure, the desired size of the pores can be achieved. It is to be understood that, the step of treating the carbon nanotube film structure with the organic solvent is optional. Additionally, the result can be accomplished by having the solvent in the dispersed solution be an acceptable organic solvent.

The dispersed solution is obtained by a step of dispersing an amount of graphene sheets into the solvent. In the present embodiment, the method for making the solvent with graphene sheets dispersed therein includes:
(a21) providing an amount of graphene sheets;
(a22) disposing the graphene sheets in the solvent to form a mixture;
(a23) ultrasonically agitating the mixture to uniformly disperse and/or suspend the graphene sheets in the solvent, thereby achieving the dispersed solution.

In one embodiment, the mixture is ultrasonically agitated for about 15 minutes. It is to be understood that, other methods can be used to disperse the graphene sheets in the solvent. For example, the mixture can be stirred mechanically.

The solvent in the dispersed solution should be able to allow dispersion of the graphene sheets and be able to evaporating totally. Ingredients of the solvent can have a small molecular weight. In one embodiment, the solvent can be water, ethanol, methanol, acetone, dichloroethane, chloroform, or combinations thereof. It is to be understood that, the solvent only acts as a medium wherein the graphene sheets are dispersed, and thus, the solvent should not react with the graphene sheets. The graphene sheets should not have a chemical reaction with the solvent, or be dissolved in the solvent.

The graphene sheet can be a single layer of graphene or multi-layers of graphene. In one embodiment, the graphene sheet includes 1 to 3 layers of graphene, thus enabling better contrast TEM imaging. The graphene is a one-atom-thick planar sheet of sp²-bonded carbon atoms that are densely packed in a honeycomb crystal lattice. The size of the graphene sheet can be very large (e.g., several millimeters). However, the size of the graphene sheet generally made is less than about 10 microns (e.g., less than 1 micron). It is to be understood that, the graphene sheet and the pore in the carbon nanotube film structure are rectangle or polygon in shape. The size of the graphene sheet represents the maximum linear distance between one point to another point both on the edge of the graphene sheet. The size of the pore represents the maximum directly distance between two points on the pore. The concentration of the graphene sheets in the dispersed solution is less than about 5% (volume/volume).

In step (b), the dispersed solution can be dropped on the surface of the carbon nanotube film structure to soak the surface thereof. It is to be understood that, when the area of the carbon nanotube film structure is relatively large, the entire carbon nanotube film structure can be immersed into the dispersed solution, and then the carbon nanotube film structure can be took out from the dispersed solution.

In one embodiment, the dispersed solution is dropped on the carbon nanotube film structure laid on the framework, drop by drop.

After the step (b), an optional step (h) of covering another carbon nanotube film structure on the surface of the carbon nanotube film structure having the dispersed solution applied thereon to form a sandwich structure.

It is to be noted that, the other carbon nanotube film structure can include one or more carbon nanotube films having a different or the same structure with the original carbon nanotube film structure. This optional step (h) and the step (b) can be repeated several times, wherein after forming the sandwich structure, the dispersed solution is further dropped on the surface of the sandwich structure, and another carbon nanotube film structure is covered on the sandwich structure. Thus, the multi-layered sandwich structure is formed that includes a plurality of carbon nanotube film structures and a plurality of dispersed solution layers sandwiched with each other. In one embodiment, the sandwich structure includes two carbon nanotube film structures and one dispersed solution layer therebetween. The carbon nanotube film structures securing the graphene sheets therebetween.

In step (c), after the solvent in the dispersed solution is evaporated, a graphene sheet layer is formed on the surface of the carbon nanotube film structure. The graphene sheets in the graphene sheet layer can be disposed on the surface of the carbon nanotube film structure in contact with each other, or separately, according to the concentration of the dispersed solution and amount of the dispersed solution applied on the surface of the carbon nanotube film structure. Referring to FIG. 7, in the graphene sheet-carbon nanotube film composite structure, at least one graphene sheet is located on at least one pore in the carbon nanotube film structure.

When a sandwich structure is formed, the graphene sheets in the graphene sheet layer are secured by the carbon nanotubes in the two carbon nanotube film structures.

After step (c), an additional step (c1) of treating the graphene sheet-carbon nanotube film composite structure can be further processed to join the graphene sheet with the carbon nanotube by a chemical bond.

The step (c1) can be a step of irradiating the graphene sheet-carbon nanotube film composite structure with a laser or an ultraviolet beam, or a step of bombarding the graphene sheet-carbon nanotube film composite structure with high-energy particles. After the treating step, the carbon atom in the graphene sheet and the carbon atom in the carbon nanotube are joined by a sp³ bond, and thus, the graphene sheets are fixed on the surface of the carbon nanotube film structure firmly. The step (c1) is optional. Without the step, the carbon nanotube and the graphene sheet are joined by Van der Waals attractive force.

In step (d), the grid has at least one through hole. The graphene sheet-carbon nanotube film composite structure covers the through hole, and is suspended across the through hole. The grid can be made of metal or other materials such as ceramics. In one embodiment, the grid is a copper grid.

When the area of the graphene sheet-carbon nanotube film composite structure is large enough, the step (d) can be replaced with a step (d1). The step (d1) includes steps of: arranging a plurality of grids spaced from each other on a substrate; covering the plurality of grids with one graphene sheet-carbon nanotube film composite structure; and cutting the graphene sheet-carbon nanotube film composite structure corresponding to the grids, and thereby producing a plurality of grids with graphene sheet-carbon nanotube film composite structure thereon at one time. A laser beam can be provided and focused between two adjacent grids. The graphene sheet-carbon nanotube film composite structure irradiated by the laser beam is burned away. The laser beam has a power of about 5 watts to 30 watts (e.g., about 18 watts).

After the step (d), an optional step (i) of treating the graphene sheet-carbon nanotube film composite structure on the grid with an organic solvent can be used to better adhere the graphene sheet-carbon nanotube film composite structure with the grid tightly. After being treated by the organic solvent, the area of contact between the carbon nanotube film structure and the grid will increase, and thus, the carbon nanotube film structure will more firmly adhere to the surface of the grid. The organic solvent can be volatile at room temperature, and can be ethanol, methanol, acetone, dichloroethane, chloroform, or any combination thereof. In one embodiment, the organic solvent is ethanol. The organic solvent should have a desirable wettability to the carbon nanotubes. More specially, the step (i) can include a step of applying the organic solvent on the surface of the graphene sheet-carbon nanotube film composite structure by using a dropper; or a step of immersing the entire graphene sheet-carbon nanotube film composite structure into a container with the organic solvent therein.

The excess portion of the graphene sheet-carbon nanotube film composite structure outside the grid can be further removed by using a laser beam focused on the excess portion.

The method for making the TEM grid has at least the following advantages. Firstly, the carbon nanotube film and the carbon nanotube film structure formed from the carbon nanotube film are free-standing, and can be easily laid and stacked. Two or more carbon nanotube film structures can sandwich the graphene sheet layer therebetween. Secondly, by using the laser, ultraviolet, or high-energy particles to treat the graphene sheet-carbon nanotube film composite structure, the graphene sheets can the carbon nanotube film structure can be combined firmly through chemical bonds. Thirdly, the carbon nanotube film structure has a large specific surface area, and is adhesive. Therefore, the carbon nanotube film structure can be directly adhered on the surface of the grid. Further, by treating with the organic solvent, the carbon nanotube film structure can be firmly secured to the grid. Fourthly, the graphene sheet-carbon nanotube film composite structure can be covered on a plurality of grids, and forming a plurality of TEM grids at one time.

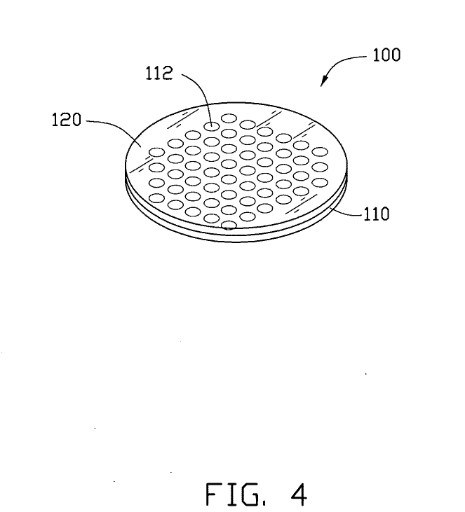

Referring to FIGS. 4, 5, and 7, a TEM grid 100, which can be made by the above-described method, includes a grid 110 and a graphene sheet-carbon nanotube film composite structure 120 covered on the grid 110.

The graphene sheet-carbon nanotube film composite structure 120 includes at least one carbon nanotube film structure 122 and at least one graphene sheet 124 disposed on a surface of the carbon nanotube film structure 122. The carbon nanotube film structure 122 includes a plurality of pores 126, wherein at least one pore 126 is covered with a graphene sheet 124.

More specifically, referring to FIGS. 2 and 3, the carbon nanotube film structure 122 includes at least two carbon nanotube films stacked with each other. The carbon nanotube film can be drawn from the carbon nanotube array, and includes a plurality of carbon nanotubes aligned substantially along the same direction and parallel to a surface of the carbon nanotube film. The carbon nanotubes in the carbon nanotube film are joined end-to-end by van der Waals attractive force therebetween. In the carbon nanotube film structure, some of the carbon nanotube films are aligned along different directions. The angle α exist between the orientation of carbon nanotubes in the two carbon nanotube films. The angle α is in the range of 0°<α≦90°. In one embodiment, α is equal to about 90 degrees.

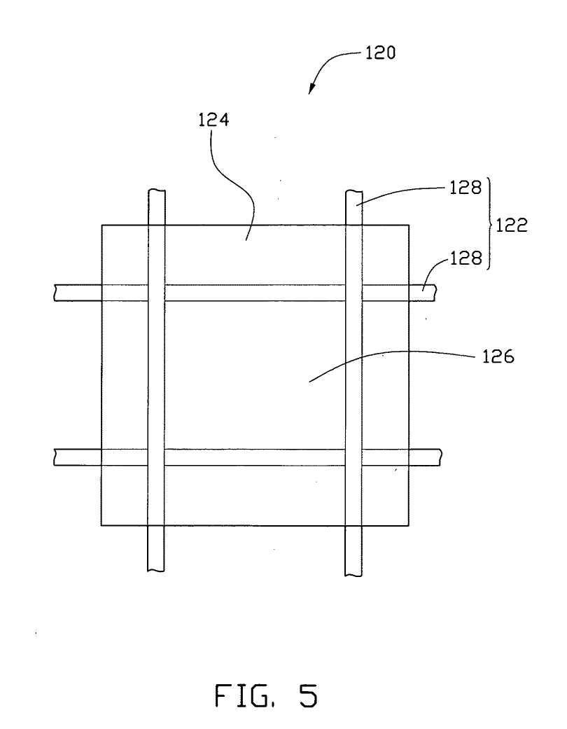

Referring to FIGS. 5 and 7, the carbon nanotube film structure 122 includes a plurality of carbon nanotube strings 128 intersecting with each other. The carbon nanotube string 128 includes paralleled carbon nanotubes. The carbon nanotube string 128 includes a plurality of carbon nanotubes joined end-to-end by van der Waals attractive force therebetween. A plurality of pores 126 are defined by the intercrossed carbon nanotube strings 128, in the carbon nanotube film structure 122. The size of the pores 126 is related to the number of layers of the carbon nanotube films in the carbon nanotube film structure 122. The number of layers of carbon nanotube films is not limited. In one embodiment, the carbon nanotube film structure 122 includes 2 to 4 layers of carbon nanotube films. The size of the pores can be in the range from about 1 nanometer to 1 micron. In one embodiment, more than 60% of the pores are nano in scale.

The graphene sheet 124 includes one or more layers of graphene. The graphene sheet 124 has a size larger than the size of the pore 126 in the carbon nanotube film structure 126 and entirely covers the pore 126. The size of the graphene sheet 124 is in the range from 2 nanometers to 10 microns. In one embodiment, the size of the graphene sheet 124 is in the range from 2 nanometers to 1 micron. In one embodiment, the graphene sheet 124 is consisted of 1 to 3 layers of graphene.

Further, the carbon atom in the graphene sheet 124 and the carbon atom in the carbon nanotube can be joined together by a sp³ bond.

Furthermore, the graphene sheet-carbon nanotube film composite structure 120 can include a plurality of carbon nanotube film structures 122 stacked with each other and a plurality of graphene sheets 124 disposed between two adjacent carbon nanotube film structures 122. The graphene sheets 124 can be secured by the carbon nanotube strings in the two adjacent carbon nanotube film structures 122 to be firmly held by the carbon nanotube film structures 122.

The grid 110 is a sheet with one or more through holes 112 therein. The grid 110 can be used in the conventional TEM grid. The material of the grid 110 can be metal or other suitable materials such as ceramics and silicon. In one embodiment, the material of the grid 110 is copper. The graphene sheet-carbon nanotube film composite structure 120 is located on the grid 110, thereby suspending portions of the graphene sheet-carbon nanotube film composite structure 120 across the through holes 112. In one embodiment, the graphene sheet-carbon nanotube film composite structure 120 is equal in size to the grid 110, and covers the entire surface of the grid 110. The through holes 112 have a diameter larger than the size of the pores 126 in the carbon nanotube film structure 122, and larger than the size of the graphene sheet 124. In one embodiment, the diameter of the through hole 112 is in the range from about 10 microns to about 2 millimeters.

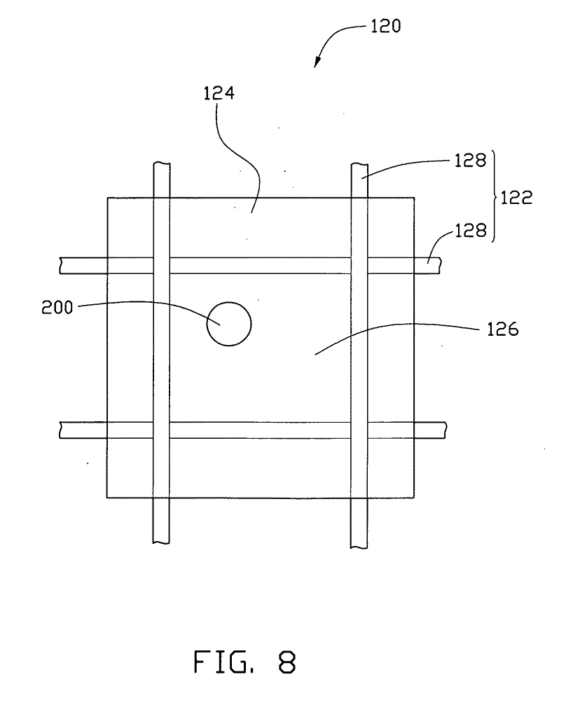

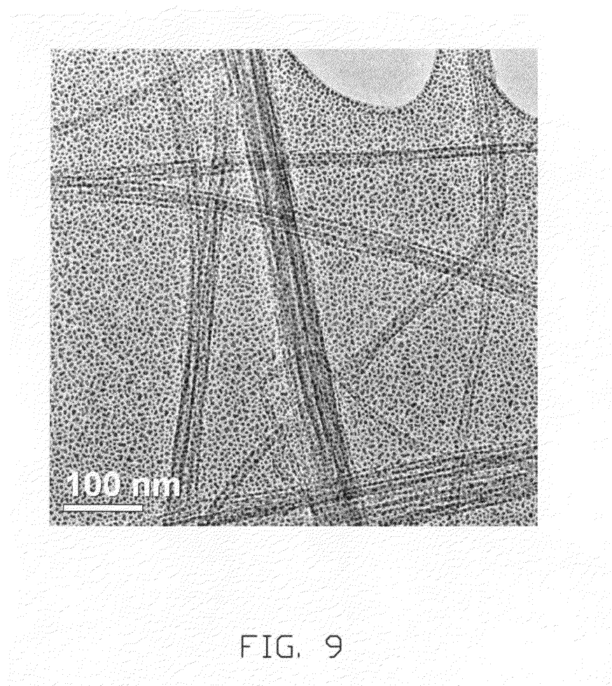

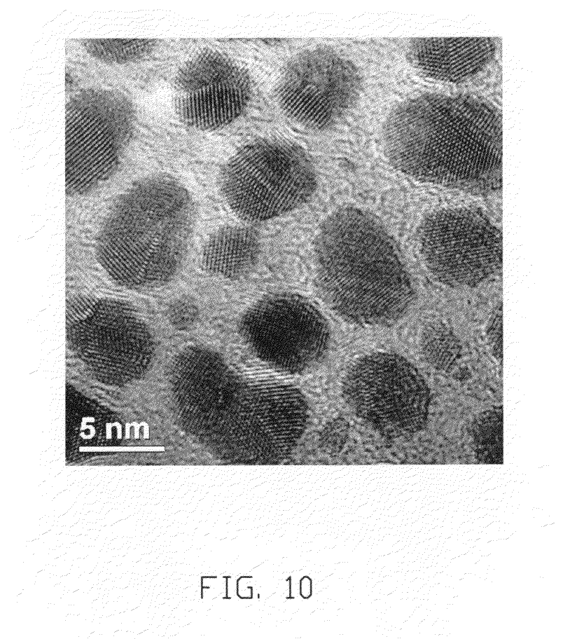

In use of the TEM grid 100, a specimen 200 is disposed on a surface of the TEM grid 100. More specifically, referring to FIGS. 8 and 9, a plurality of specimens 200 are disposed on the surface of the graphene sheet 124 covered the pore 126 of the carbon nanotube film structure 122. The specimens 200 can be nano-scaled particles, such as nanowires, nanotubes, and nanoballs. The size of a single specimen 200 can be smaller than 1 micron. In one embodiment, the size of the single specimen 200 can be smaller than 10 nanometers. Referring to FIGS. 9 and 10, the specimen 200 is an amount of nano-scaled gold powder. The nano-scaled gold powder can be dispersed in a solvent and dropped on the surface of the TEM grid 100. The solvent is dried, and TEM photos with different resolutions can be achieved. The black spots in FIG. 9 are the gold powder.

The TEM grid 100 has at least the following advantages.

Firstly, the graphene sheet 124 carries the specimen 200. A large amount of specimens 200 can be uniformly distributed on the surface of the graphene sheet 124, and the TEM photo can be used to analyze the size distribution of the specimens 200, and observing the self-assembling of the large amount of specimens 200 on the surface of the graphene sheet 124. The graphene sheet 124 covers the pore 126, and the specimens 200 are carried by the graphene sheet 124, and thus, the specimens 200 are uniformly distributed above the pore 126, thereby achieving a maximum carrying probability of the specimens 200. It is to be understood that the size of the single specimen 200 can be only a little smaller than the size of the pore 126.

Secondly, a graphene sheet 126 with a larger size is difficult to be formed. The graphene sheet 124 formed by using a conventional method are limited to 10 microns. The pore 126 can be nano in scale, and thus the graphene sheet 124 with smaller size can cover the entire pore 126. A size equal to or larger than 1 nanometer and smaller than 100 nanometer is nano in scale.

Thirdly, the graphene sheet is very thin. The graphene has a thickness of about 0.335 nanometers. Therefore, the background noise during the TEM observation can be lowered, and the TEM photos having higher resolution can be achieved. Further, the smaller the through hole 112 of the grid 110 (e.g., below 2 microns), the more complicated the method of manufacture. The TEM grid 100 can use a grid 110 with the through hole 112 with a larger diameter.

Fourthly, due to a high purity of the carbon nanotube film drawn from the carbon nanotube array, the TEM grid 100 including the carbon nanotube films do not require elimination of impurities by using a thermal treating step.

Further, the carbon nanotube film structure 122 and the graphene sheet 124 are both composed of carbon atoms, and have a similar structure (graphene), thus, the properties of the carbon nanotube film structure 122 and the graphene sheet 124 is similar, and the carbon nanotube film structure 122 can be joined together with the graphene sheet 124 by sp³ bonds. The TEM grid 100 including the sp³ bonds can be more durable.

Furthermore, the graphene sheet-carbon nanotube film composite structure 120 can include at least two carbon nanotube film structures 122 securing the graphene sheets 124 therebetween. Thus, the TEM grid 100 will have a stable structure and can be more durable.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

It is also to be understood that the above description and the claims drawn to a method may include some indication in reference to certain steps. However, the indication used is only to be viewed for identification purposes and not as a suggestion as to an order for the steps.

What is claimed is:

1. A graphene sheet-carbon nanotube film composite structure comprising:
at least one carbon nanotube film structure comprising a plurality of carbon nanotubes, the plurality of carbon nanotubes defining at least one pore; and
at least one graphene sheet disposed on a surface of the carbon nanotube film structure and covering the at least one pore.

2. The graphene sheet-carbon nanotube film composite structure of claim 1, wherein the carbon nanotube film structure comprises a plurality of stacked carbon nanotube films, and at least two of the plurality of stacked carbon nanotube films are aligned along different directions.

3. The graphene sheet-carbon nanotube film composite structure of claim 2, wherein the carbon nanotube film comprises a plurality of carbon nanotubes aligned substantially along a same direction and joined end-to-end by van der Waals attractive force therebetween.

4. The graphene sheet-carbon nanotube film composite structure of claim 2, wherein the carbon nanotube film is drawn from a carbon nanotube array.

5. The graphene sheet-carbon nanotube film composite structure of claim 1, wherein the graphene sheet and a carbon nanotube in the carbon nanotube film structure is joined by at least one sp³ bond.

6. The graphene sheet-carbon nanotube film composite structure of claim 1, wherein the carbon nanotube film structure comprises a plurality of stacked carbon nanotube films, and the at least one graphene sheet is disposed between two adjacent carbon nanotube film structures.

7. A transmission electron microscope grid comprising:
a grid; and
a graphene sheet-carbon nanotube film composite structure located on the grid, a portion of the graphene sheet-carbon nanotube film composite structure being suspended;
wherein the graphene sheet-carbon nanotube film composite structure comprises of at least one carbon nanotube film structure and at least one graphene sheet, the carbon nanotube film structure comprises a plurality of carbon nanotubes, the plurality of carbon nanotubes defines at least one pore, and the at least one pore is covered by the at least one graphene sheet.

8. The transmission electron microscope grid of claim 7, wherein a size of the graphene sheet is in a range from about 2 nanometers to about several millimeters.

9. The transmission electron microscope grid of claim 7, wherein a size of the graphene sheet is in a range from about 2 nanometers to about 1 micron.

10. The transmission electron microscope grid of claim 7, wherein the graphene sheet comprises 1 to 3 layers of graphene.

11. The transmission electron microscope grid of claim 7, wherein the carbon nanotube film structure comprises a plurality of carbon nanotubes aligned substantially along a same direction and joined end-to-end by van der Waals attractive force therebetween.

12. The transmission electron microscope grid of claim 11, wherein the carbon nanotube film structure comprises a plurality of stacked carbon nanotube films, wherein at least two adjacent carbon nanotube films are aligned along different directions.

13. The transmission electron microscope grid of claim 7, wherein a size of the pore is in a range from about 1 nanometer to about 1 micron.

14. The transmission electron microscope grid of claim 13, wherein the carbon nanotube film structure defining a plurality of pores, at least 60% of the pores in the carbon nanotube film structure are less than 100 nanometers.

15. The transmission electron microscope grid of claim 7, wherein a carbon atom in the graphene sheet and a carbon atom in a carbon nanotube in the carbon nanotube film structure is joined by a sp³ bond.

16. The transmission electron microscope grid of claim 7, wherein the graphene sheet-carbon nanotube film composite structure comprises a plurality of carbon nanotube film structures stacked with each other, and a plurality of graphene sheets are disposed between two adjacent carbon nanotube film structures.

17. The transmission electron microscope grid of claim 7, wherein the grid comprises at least one through hole, a diameter of the through hole is in a range from about 10 microns to about 2 millimeters.

18. A transmission electron microscope grid comprising:
a grid; and
a graphene sheet-carbon nanotube film composite structure covered on the grid and partially suspended, the graphene sheet-carbon nanotube film composite structure comprising at least one carbon nanotube film structure and a plurality of graphene sheets, the carbon nanotube film structure comprising a plurality of intersected carbon nanotube strings that define a plurality of pores, at least one of the plurality of pores being covered by at least one of the plurality of graphene sheets.

19. The transmission electron microscope grid of claim 18, wherein the carbon nanotube string comprises a plurality bundled carbon nanotubes.

20. The transmission electron microscope grid of claim 19, wherein the carbon nanotube string comprises a plurality of carbon nanotubes aligned substantially along a same direction and joined end-to-end by van der Waals attractive force therebetween.
